(19) United States
(12) Patent Application Publication
(10) Pub. No.: US 2026/0279678 A1
(43) Pub. Date: Sep. 17, 2026

(54) MULTILAYER ELECTRONIC COMPONENT AND BOARD HAVING THE SAME MOUNTED THEREON

(71) Applicant: SAMSUNG ELECTRO-MECHANICS CO., LTD., Suwon-si (KR)

(72) Inventors: Soo Hwan SON, Suwon-si (KR); Yeong Lim KWON, Suwon-si (KR); Se Hun PARK, Suwon-si (KR); Jeong Pil JHUN, Suwon-si (KR)

(73) Assignee: SAMSUNG ELECTRO-MECHANICS CO., LTD., Suwon-si (KR)

(21) Appl. No.: 19/455,050

(22) Filed: Jan. 21, 2026

(30) Foreign Application Priority Data
Mar. 11, 2025 (KR) 10-2025-0031281

(51) Int. Cl. H01G 4/30; H01G 4/232

(52) U.S. Cl. CPC H01G 4/30; H01G 4/2325

(57) ABSTRACT

A multilayer electronic component includes a body including a dielectric layer and an internal electrode alternately disposed with the dielectric layer interposed therebetween in a thickness direction; an external electrode disposed on the body in a length direction; and a connection terminal disposed on one surface of the external electrode, and including a recess portion in a region recessed from the outside to the inside thereof in the length direction, wherein a round portion is provided on at least one corner of the connection terminal, and a radius of the round portion is 30 μm or more and 196 μm or less.

### CROSS-REFERENCE TO RELATED APPLICATION(S)

This application claims benefit of priority to Korean Patent Application No. 10-2025-0031281 filed on Mar. 11, 2025, the disclosure of which is incorporated herein by reference in their entireties.

### TECHNICAL FIELD

The present disclosure relates to a multilayer electronic component and a mounting substrate thereof.

A multilayer ceramic capacitor (MLCC), a multilayer electronic component, may be a chip-type condenser mounted on the printed circuit boards of various types of electronic products, such as an imaging device, including a liquid crystal display (LCD) or a plasma display panel (PDP), a computer, a smartphone, or a mobile phone, serving to charge or discharge electricity therein or therefrom.

Such a multilayer ceramic capacitor has a small size, implements high capacitance, and is easily mounted on a circuit board, and may thus be used as a component in various electronic devices. There has been increasing demand for a multilayer ceramic capacitor to have a reduced size and higher capacitance as each of various electronic devices such as a computer and a mobile device have a reduced size and higher output.

A multilayer ceramic capacitor, a multilayer electronic component, includes a dielectric material, and since the dielectric material has piezoelectricity, the dielectric material may be deformed in synchronization with an applied voltage.

Piezoelectric vibrations of the MLCC may be generated by the applied AC voltage, and the vibrations of the MLCC may be transmitted to a substrate through the MLCC and solder, causing the substrate to vibrate. When noise caused by the substrate vibrations is within an audible frequency range, it is heard as noise, and this sound is known as acoustic noise.

This acoustic noise may be perceived as an abnormal sound by a user in a quiet environment, potentially indicating a malfunction. In addition, in a device having an audio circuit, acoustic noise may be superimposed on an audio output, degrading device' quality. In addition, when the noise generated by the vibrations of the substrate exceeds 20 kHz, separate from the acoustic noise perceived by the human ear, it can cause malfunctions in various sensors used in IT and industrial/electronic product fields.

Since small multilayer ceramic capacitors are densely mounted at narrow intervals on the substrate, mountability may be also evaluated as an important factor, and it is important to dispose the same in the intended mounting location after performing a reflow process after applying solder. When a mounting defect occurs, it can have an adverse effect on the entire product.

### SUMMARY

An aspect of the present disclosure is to provide a multilayer electronic component having improved acoustic noise.

An aspect of the present disclosure is to provide a multilayer electronic component having improved mountability.

However, various problems to be solved by the present disclosure are not limited to the above-described contents, and can be more easily understood in the process of explaining specific embodiments of the present disclosure.

According to an aspect of the present disclosure, a multilayer electronic component may include a body including a dielectric layer and an internal electrode alternately disposed with the dielectric layer interposed therebetween in a thickness direction, the body including first and second surfaces opposing each other in the thickness direction, third and fourth surfaces connected to the first and second surfaces and opposing each other in a length direction, and fifth and sixth surfaces connected to the first to fourth surfaces and opposing each other in a width direction; a first external electrode including a first connection portion disposed on the third surface, and a first band portion disposed to extend from the first connection portion to a portion of the first and second surfaces; a second external electrode including a second connection portion disposed on the fourth surface, and a second band portion disposed to extend from the second connection portion to a portion of the first and second surfaces; a first connection terminal disposed to be in contact with the first band portion, and including a first recess portion in a region recessed toward the fourth surface; and a second connection terminal disposed to be in contact with the second band portion, and including a second recess portion in a region recessed toward the third surface, wherein a first round portion may be provided on at least one corner of the first connection terminal, a second round portion may be provided on at least one corner of the second connection terminal, and radii of the first and second round portions may be 30 μm or more and 196 μm or less.

According to another aspect of the present disclosure, a mounting substrate of a multilayer electronic component may include a substrate; first and second electrode pads disposed on the substrate; and the multilayer electronic component described above, wherein the first and second connection terminals may be mounted on the substrate to be bonded to the first and second electrode pads, respectively, and solder may be disposed on at least a portion of the first and second recess portions.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 schematically illustrates a perspective view of a multilayer electronic component according to an embodiment of the present disclosure;

FIG. 2 schematically illustrates a bottom view of the multilayer electronic component of FIG. 1;

FIG. 3 schematically illustrates a connection terminal of an embodiment of the present disclosure;

FIG. 4 schematically illustrates a cross-sectional view taken along line I-I′ of FIG. 1;

FIG. 5 schematically illustrates a cross-sectional view taken along line II-II′ of FIG. 1;

FIG. 6 schematically illustrates a perspective view of a multilayer electronic component according to another embodiment of the present disclosure;

FIG. 7 schematically illustrates a connection terminal according to another embodiment of the present disclosure; and

FIG. 8 schematically illustrates a mounting substrate of a multilayer electronic component according to another embodiment of the present disclosure.

### DETAILED DESCRIPTION

Hereinafter, some embodiments of the present disclosure will be described as follows with reference to the attached drawings. The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. Accordingly, shapes and sizes of elements in the drawings may be exaggerated for clear description, and elements indicated by the same reference numeral are the same elements in the drawings.

In the drawings, irrelevant descriptions will be omitted to clearly describe the present disclosure, and to clearly express a plurality of layers and areas, thicknesses may be magnified. The same elements having the same function within the scope of the same concept will be described with use of the same reference numerals. Throughout the specification, when a component is referred to as “comprise” or “comprising,” it means that it may further include other components as well, rather than excluding other components, unless specifically stated otherwise.

In the drawing, a Z-direction may be defined as a thickness direction or a first direction, an X-direction may be defined as a length direction or a second direction, and a Y-direction may be defined as a width direction or a third direction. A stacking direction may be the thickness direction or the width direction.

### Multilayer Electronic Component

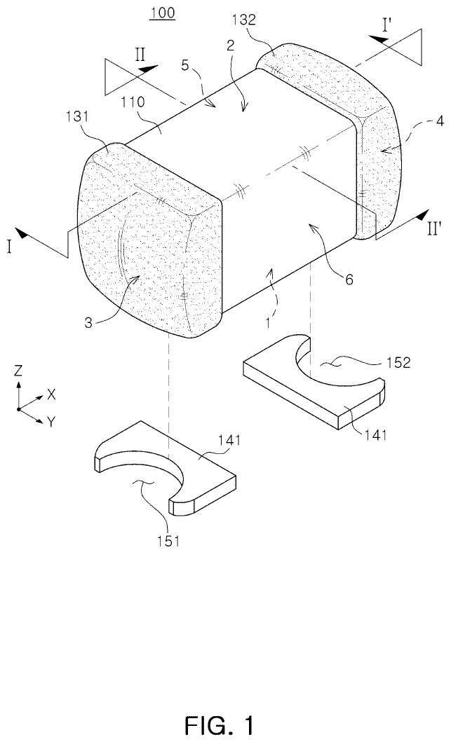

FIG. 1 schematically illustrates a perspective view of a multilayer electronic component according to an embodiment of the present disclosure.

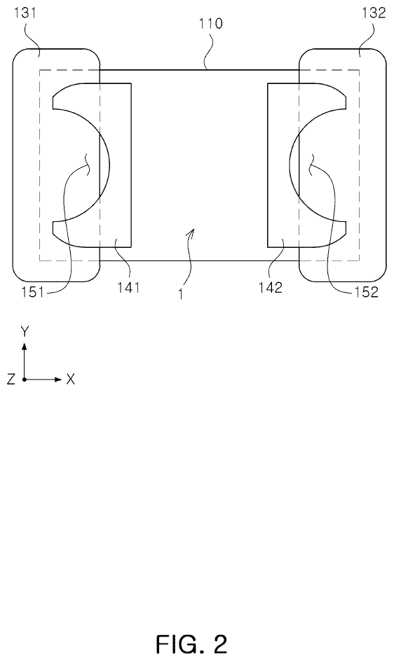

FIG. 2 schematically illustrates a bottom view of the multilayer electronic component of FIG. 1.

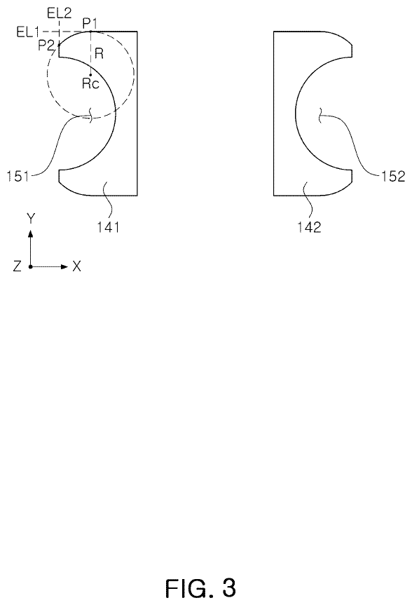

FIG. 3 schematically illustrates a connection terminal of an embodiment of the present disclosure.

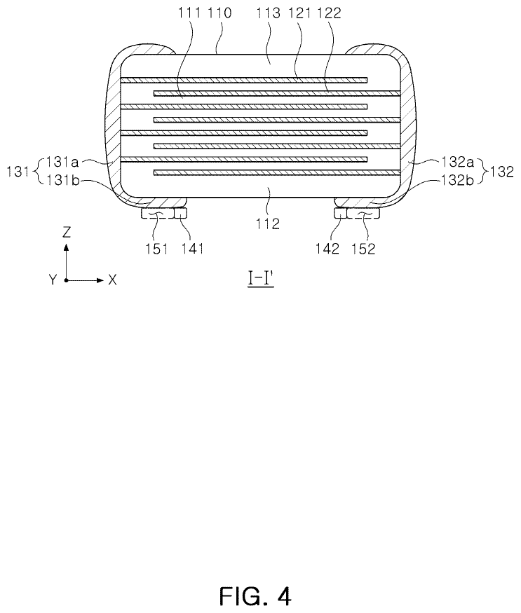

FIG. 4 schematically illustrates a cross-sectional view taken along line I-I′ of FIG. 1.

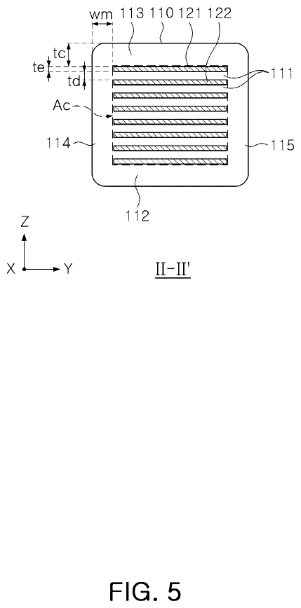

FIG. 5 schematically illustrates a cross-sectional view taken along line II-II′ of FIG. 1.

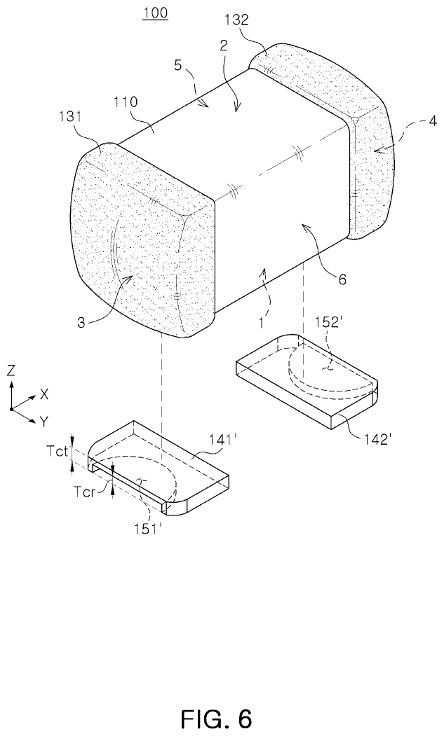

FIG. 6 schematically illustrates a perspective view of a multilayer electronic component according to another embodiment of the present disclosure.

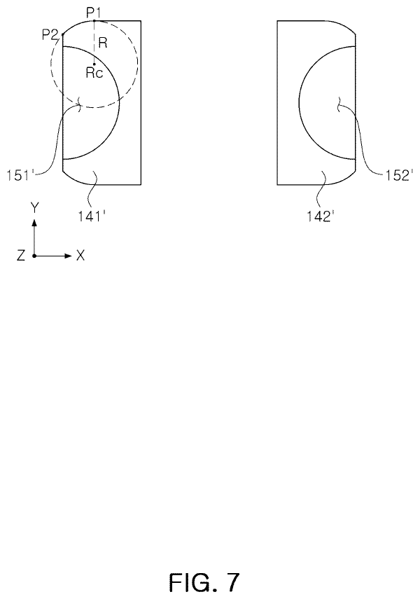

FIG. 7 schematically illustrates a connection terminal according to another embodiment of the present disclosure.

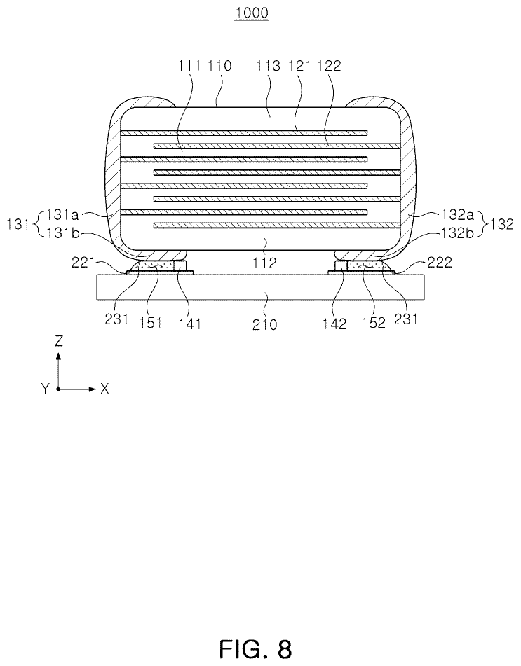

FIG. 8 schematically illustrates a mounting substrate of a multilayer electronic component according to another embodiment of the present disclosure.

Hereinafter, a multilayer electronic component and a mounting substrate thereof according to an embodiment of the present disclosure will be described in detail with reference to FIGS. 1 to 8. However, a multilayer ceramic capacitor will be described as an example of a multilayer electronic component, but the example embodiment may also be applied to various electronic products using a dielectric composition, such as an inductor, a piezoelectric element, a varistor, a thermistor, or the like.

A multilayer electronic component 100 according to an embodiment of the present disclosure may include a body including a dielectric layer 111 and internal electrodes 121 and 122 alternately disposed with the dielectric layer 111 interposed therebetween in a thickness direction, the body including first and second surfaces 1 and 2 opposing each other in the thickness direction, third and fourth surfaces 3 and 4 connected to the first and second surfaces 1 and 2 and opposing each other in a length direction, and fifth and sixth surfaces 5 and 6 connected to the first to fourth surfaces 1, 2, 3, and 4 and opposing each other in a width direction; a first external electrode 131 including a first connection portion 131a disposed on the third surface 3, and a first band portion 131b disposed to extend from the first connection portion 131a to a portion of the first and second surfaces; a second external electrode 132 including a second connection portion 132a disposed on the fourth surface 4, and a second band portion 132b disposed to extend from the second connection portion 132a to a portion of the first and second surfaces 1 and 2; a first connection terminal 141 disposed to be in contact with the first band portion 131a, and including a first recess portion 151 in a region recessed toward the fourth surface 4; and a second connection terminal 142 disposed to be in contact with the second band portion 132a, and including a second recess portion 152 in a region recessed toward the third surface 3, wherein a first round portion may be provided on at least one corner of the first connection terminal 141, a second round portion may be provided on at least one corner of the second connection terminal 142, and radii of the first and second round portions may be 30 μm or more and 196 μm or less.

The body 110 may have the dielectric layer 111 and the internal electrodes 121 and 122 alternately stacked.

More specifically, the body 110 may include a capacitance forming portion (Ac) disposed in the body 110, and including a first internal electrode 121 and a second internal electrode 122, alternately disposed to oppose each other with the dielectric layer 111 interposed therebetween, to form capacitance.

The body 110 is not limited to a particular shape, and may have a hexahedral shape or a shape similar to the hexahedral shape, as illustrated in the drawings. The body 110 may not have the shape of a hexahedron having perfectly straight lines because ceramic powder particles included in the body 110 are contracted in a process in which the body is sintered. However, the body 110 may have a substantially hexahedral shape.

The body 110 may have first and second surfaces 1 and 2 opposing each other in the thickness direction, third and fourth surfaces 3 and 4 connected to the first and second surfaces 1 and 2 and opposing each other in the length direction, and fifth and sixth surfaces 5 and 6 connected to the first to fourth surfaces 1, 2, 3, and 4 and opposing each other in the width direction.

A plurality of dielectric layers 111 forming the body 110 may be in a sintered state, and adjacent dielectric layers 111 may be integrated with each other, such that boundaries therebetween may not be readily apparent without a scanning electron microscope (SEM).

A raw material for forming the dielectric layer 111 is not particularly limited, as long as sufficient capacitance may be obtained therewith. In general, a perovskite (ABO₃)-based material may be used, and for example, a barium titanate-based material, a lead composite perovskite-based material, a strontium titanate-based material, or the like, may be used. The barium titanate-based material may include BaTiO₃-based ceramic particles, and examples of the ceramic particles may include BaTiO₃, or (Ba₁₋ₓCaₓ)TiO₃(0<x<1), Ba(Ti_{1-y}Ca_{y})O₃(0<y<1), (Ba₁₋ₓCaₓ)Ti_{1-y}Zr_{y})O₃(0<x<1, 0<y<1), Ba(Ti_{1-y}Zr_{y})O₃(0<y<1), or the like, in which calcium (Ca), zirconium (Zr), or the like is partially dissolved in BaTiO₃, or the like.

In addition, the raw material for forming the dielectric layer 111 may include various ceramic additives, organic solvents, binders, dispersants, and the like, added to powder particles such as barium titanate (BaTiO₃) powder particles, or the like, according to an object of the present disclosure.

Meanwhile, in order to distinguish the dielectric layer from dielectric layers included in cover portions 112 and 113 and side margin portions 114 and 115, to be described later, the dielectric layer in the capacitance forming portion (Ac) may be defined as a first dielectric layer, the dielectric layer in the cover portions 112 and 113 may be defined as a second dielectric layer, and the dielectric layer in the side margin portions 114 and 115 may be defined as a third dielectric layer.

Since the first to third dielectric layers may be formed using a dielectric material such as barium titanate (BaTiO₃), the first to third dielectric layers may include a dielectric microstructure after sintering. The dielectric microstructure may include a plurality of grains, grain boundaries disposed between the adjacent grains, and triple points disposed at points at which three or more of the grain boundaries contact each other, and may include a plurality of grains, a plurality of grain boundaries, and a plurality of triple points, respectively.

A thickness “td” of the dielectric layer 111 is not particularly limited.

However, to facilitate miniaturization and high capacitance of the multilayer electronic component, an upper limit value of the thickness “td” of the dielectric layer 111 may be 1.5 μm or less, 1.2 μm or less, 1.0 μm or less, 0.8 μm or less, or 0.6 μm or less. To achieve ultra-miniaturization, the thickness “td” of the dielectric layer 111 may be 0.5 μm or less, or 0.4 μm or less, and a lower limit value thereof may be 0.1 μm or more, 0.2 μm or more, or 0.3 μm or more.

Here, the thickness “td” of the dielectric layer 111 may mean the thickness “td” of the dielectric layer 111 disposed between the first and second internal electrodes 121 and 122.

In this case, the thickness “td” of the dielectric layer 111 may be a concept including the thickness “td” of any one of a plurality of dielectric layers 111, or may be a concept including the thickness “td” of each of the dielectric layers 111.

In addition, the thickness “td” of the dielectric layer 111 may mean an average thickness “td” of a single dielectric layer 111, may mean an average thickness “td” of each of the plurality of dielectric layers 111, or may mean an average thickness “td” of the plurality of dielectric layers 111.

The average thickness “td” of the dielectric layer 111 may be measured by scanning images of cross-sections of the body 110 in the length and width directions with a scanning electron microscope (SEM) at a magnification of 10,000×. More specifically, the average thickness “td” of a single dielectric layer 111 may mean an average value calculated by measuring a thickness of a single dielectric layer 111 in the length direction at 5 equally spaced points in the length direction in the scanned image. The 5 equally spaced points may be designated in the capacitance forming portion (Ac). In addition, when such an average value is measured by extensively using measurement of the average value to 3 dielectric layers 111, the average thickness “td” of the plurality of dielectric layers 111 may be further generalized.

The internal electrodes 121 and 122 may be alternately stacked with the dielectric layer 111.

The internal electrodes 121 and 122 may include a first internal electrode 121 and a second internal electrode 122, and the first and second internal electrodes 121 and 122 may be alternately disposed to oppose each other with the dielectric layers 111, constituting the body 110, interposed therebetween, and may be exposed to the third and fourth surfaces 3 and 4 of the body 110, respectively.

More specifically, the first internal electrode 121 may be spaced apart from the fourth surface 4 and exposed through the third surface 3, and the second internal electrode 122 may be spaced apart from the third surface 3 and exposed through the fourth surface 4. A first external electrode 131 may be disposed on the third surface 3 of the body 110 and connected to the first internal electrode 121, and a second external electrode 132 may be disposed on the fourth surface 4 of the body 110 and connected to the second internal electrode 122.

That is, the first internal electrode 121 may not be connected to the second external electrode 132 but may be connected to the first external electrode 131, and the second internal electrode 122 may not be connected to the first external electrode 131 but may be connected to the second external electrode 132. In this case, the first and second internal electrodes 121 and 122 may be electrically separated from each other by the dielectric layer 111 interposed therebetween.

Meanwhile, the body 110 may be formed by alternately stacking a first ceramic green sheet on which a paste for a first internal electrode, to become the first internal electrode 121, is printed, and a second ceramic green sheet on which a paste for a second internal electrode, to become the second internal electrode 122, is printed, and then sintering the stacked ceramic green sheets. The printing method of the conductive paste for the internal electrode may use a screen-printing method or a gravure printing method, but the present disclosure is not limited thereto.

A material for forming the internal electrodes 121 and 122 is not particularly limited, and a material having excellent electrical conductivity may be used. For example, the internal electrodes 121 and 122 may include at least one of nickel (Ni), copper (Cu), palladium (Pd), silver (Ag), gold (Au), platinum (Pt), tin (Sn), tungsten (W), titanium (Ti), and alloys thereof.

Meanwhile, a thickness “te” of the internal electrodes 121 and 122 is not particularly limited, and hereinafter, the description of the thickness “te” of the internal electrodes 121 and 122 may mean a thickness “te” of each of the first internal electrode 121 and the second internal electrode 122.

In order to achieve miniaturization and high capacitance of the multilayer electronic component 100, the thickness “te” of the internal electrode 121 and 122 may be 1.0 μm or less, 0.8 μm or less, or 0.6 μm or less, and in order to achieve ultra-miniaturization, the thickness “te” thereof may be 0.5 μm or less, or 0.4 μm or less.

In this case, the thickness “te” of the internal electrodes 121 and 122 may be a concept including a thickness “te” of at least one of a plurality of internal electrodes 121 and 122, or may be a concept including a thickness “te” of all the internal electrodes 121 and 122.

In this case, the thickness “te” of the internal electrodes 121 and 122 may be a concept including the thickness “te” of at least one of the plurality of internal electrodes 121 and 122, or may be a concept including the thickness “te” of each of all the internal electrodes 121 and 122.

In addition, the thickness “te” of the internal electrodes 121 and 122 may an average thickness “te” of one internal electrode 121, 122, or may mean an average thickness “te” of each of the plurality of internal electrodes 121 and 122, or may mean an average thickness “te” of the plurality of internal electrodes 121 and 122.

The average thickness “te” of the internal electrodes 121 and 122 may be measured by scanning images of cross-sections of the body 110 in the length and thickness directions with a scanning electron microscope (SEM) at a magnification of 10,000×. More specifically, the average thickness “te” of one internal electrode 121, 122 may be an average value calculated by measuring a thickness of one internal electrode at 5 equally spaced points in the length direction in the scanned image. The 5 equally spaced points may be designated in the capacitance forming portion (Ac). In addition, when such an average value is measured by extensively using measurements of the average value to 3 internal electrodes 121 and 122, the average thickness “te” of the plurality of internal electrodes 121 and 122 may be further generalized.

Meanwhile, the body 110 may include cover portions 112 and 113 disposed on both end surfaces of the capacitance forming portion (Ac) in the thickness direction.

Specifically, the cover portions 112 and 113 may include a first cover portion 112 disposed on one surface of the capacitance forming portion (Ac) in the thickness direction and a second cover portion 113 disposed on the other surface of the capacitance forming portion (Ac) in the thickness direction. More specifically, for example, the cover portions 112 and 113 may include a first cover portion 112 disposed below the capacitance forming portion (Ac) in the thickness direction and a second cover portion 113 disposed above the capacitance forming portion (Ac) in the thickness direction.

The first cover portion 112 and the second cover portion 113 may be formed by disposing or stacking a single second dielectric layer or two or more second dielectric layers on upper and lower surfaces of the capacitance forming portion (Ac) in the thickness direction, respectively, and may basically play a role in preventing damage to the internal electrodes 121 and 122 due to physical or chemical stress.

The first cover portion 112 and the second cover portion 113 may not include the internal electrodes 121 and 122, and may include the same dielectric material as the first dielectric layer 111 of the capacitance forming portion (Ac). That is, the first cover portion 112 and the second cover portion 113 may include a dielectric material, for example, a barium titanate (BaTiO₃)-based dielectric material.

Meanwhile, the thickness “tc” of the cover portions 112 and 113 is not particularly limited, and hereinafter, the description of the thickness “tc” of the cover portions 112 and 113 may mean the thickness “tc” of each of the first cover portion 112 and the second cover portion 113.

However, to more easily achieve miniaturization and high capacitance of the multilayer electronic component 100, an upper limit value of the thickness “tc” of the cover portions 112 and 113 may be 100 μm or less or 50 μm or less, and preferably 30 μm or less, and in the case of ultra-small products, the thickness “tc” thereof may be more preferably 20 μm or less, and a lower limit value thereof may be 5 μm or more, 10 μm or 20 μm or more.

Here, the thickness “tc” of the cover portions 112 and 113 may mean an average thickness of the cover portions 112 and 113.

In addition, the average thickness “tc” of the cover portions 112 and 113 may mean an average thickness “tc” of each of the first and second cover portions 112 and 113, or may mean an average thickness “tc” of the first and second cover portions 112 and 113.

The average thickness “tc” of the cover portions 112 and 113 may be measured by scanning images of cross-sections of the body 110 in the length and thickness directions with a scanning electron microscope (SEM) at a magnification of 10,000×. More specifically, the average thickness “tc” may be an average size calculated by measuring the thickness at 5 equally spaced points in the length direction in the scanned image of one cover portion 112, 113.

In addition, the average thickness “tc” of the cover portions 112 and 113 measured by the above-described method may be substantially the same as the average thickness of the cover portions 112 and 113, in the cross-sections of the body 110 in the width and thickness directions.

Meanwhile, the multilayer electronic component 100 may include side margin portions 114 and 115, which are end regions of the internal electrodes 121 and 122 in the width direction.

More specifically, the side margin portions 114 and 115 may include a first side margin portion 114 disposed between the internal electrodes 121 and 122 and the fifth surface 5 and a second side margin portion 115 disposed between the internal electrodes 121 and 122 and the sixth surface 6.

As illustrated, the side margin portions 114 and 115 may refer to regions between both ends of the first and second internal electrodes 121 and 122 in the width direction and a boundary surface of the body 110, based on the cross-sections of the body 110 in the width and thickness directions.

The side margin portions 114 and 115 may refer to a ceramic green sheet region except for a region in which a paste for internal electrodes is applied, when a paste for internal electrodes is applied to a ceramic green sheet applied to the capacitance forming portion (Ac), except for a region in which the side margin portions 114 and 115 are to be formed, or may also refer to a region after sintering.

However, the present disclosure is not particularly limited thereto, the side margin portions 114 and 115 may be formed by applying a conductive paste to a ceramic green sheet applied to the capacitance forming portion (Ac), except for a region in which the margin portions 114 and 115 are to be formed, to form internal electrodes 121 and 122, and to suppress a step difference due to the internal electrodes 121 and 122, cutting the body 110 so that the internal electrodes 121 and 122 after lamination are exposed to the fifth and sixth surfaces 5 and 6 of the body, and then disposing and stacking a single third dielectric layer or two or more third dielectric layers in the width direction on both end-surfaces of the capacitance forming portion (Ac) in the width direction.

The side margin portions 114 and 115 may basically play a role in preventing damage to the internal electrodes 121 and 122 due to physical or chemical stress.

The first side margin portion 114 the second side margin portion 115 may not include the internal electrodes 121 and 122, and may include the same dielectric material as the dielectric layer 111, and may correspond to, for example, a portion of the first dielectric layer 111. That is, the first side margin portion 114 and the second side margin portion 115 may include a dielectric material, and may include, for example, a barium titanate (BaTiO₃)-based dielectric material.

Meanwhile, a width “wm” of the side margin portions 114 and 115 is not particularly limited, and hereinafter, the description of the width “wm” of the side margin portions 114 and 115 may mean the width “wm” of each of the first side margin portion 114 and the second side margin portion 115.

To more easily achieve miniaturization and high capacitance of the multilayer electronic component 100, the width “wm” of the side margin portions 114 and 115 may be 50 μm or less, and preferably 30 μm or less, and in the case of ultra-small products, the width “wm” thereof may be more preferably 20 μm or less.

Here, the width “wm” of the side margin portions 114 and 115 may mean an average width “wm” of the side margin portions 114 and 115.

In addition, the average width “wm” of the side margin portions 114 and 115 may mean an average width “wm” of each of the first and second side margin portions 114 and 115, or may mean an average width “wm” of the first and second side margin portions 114 and 115.

An average width “wm” of the side margin portions 114 and 115 may be measured by scanning images of cross-sections of the body 110 in the width and thickness directions with a scanning electron microscope (SEM) at a magnification of 10,000×. More specifically, the average width “wm” of the side margin portions 114 and 115 may refer to an average value calculated by measuring widths thereof at 5 equally spaced points in the thickness direction in the scanned image of one side margin portion 114, 115.

In an embodiment of the present disclosure, a structure in which the multilayer electronic component 100 has two external electrodes 131 and 132 is illustrated, but the number, shapes, or the like of the external electrodes 131 and 132 may be changed, depending on the shape of the internal electrodes 121 and 122, or other purposes.

The external electrodes 131 and 132 may be disposed on the body 110 and connected to the internal electrodes 121 and 122.

More specifically, the external electrodes 131 and 132 may include first and second external electrodes 131 and 132 respectively disposed on the third and fourth surfaces 3 and 4 of the body 110, and respectively connected to the first and second internal electrodes 121 and 122. That is, the first external electrode 131 may be disposed on the third surface 3 of the body and connected to the first internal electrode 121, and the second external electrode 132 may be disposed on the fourth surface 4 of the body and connected to the second internal electrode 122.

In addition, the external electrodes 131 and 132 may be disposed to extend to a portion of the first and second surfaces 1 and 2 of the body 110, or may be disposed to extend to a portion of the fifth and sixth surfaces 5 and 6 of the body 110. That is, the first external electrode 131 may be disposed on the third surface 3 of the body 110 and portions of the first, second, fifth, and sixth surfaces 1, 2, 5, and 6 of the body 110, and the second external electrode 132 may be disposed on the fourth surface 4 of the body 110 and portions of the first, second, fifth, and sixth surfaces 1, 2, 5, and 6 of the body 110.

Specifically, the external electrodes 131 and 132 may include connection portions 131a and 132a disposed on the third and fourth surfaces 3 and 4 of the body 110, and band portions 131b and 132b disposed to extend from the connection portions 131a and 132a to a portion of the first and second surfaces 1 and 2 of the body 110.

More specifically, the first external electrode 131 may include a first connection portion 131a disposed on the third surface 3 of the body 110, and a first band portion 131b disposed to extend from the first connection portion 131a to a portion of the first and second surfaces 1 and 2, and the second external electrode 132 may include a second connection portion 132a disposed on the fourth surface 4 of the body 110, and a second band portion 132b disposed to extend from the second connection portion 132a to a portion of the first and second surfaces 1 and 2.

The first band portion 131b may include a 1-1 band portion extending from the first connection portion 131a to a portion of the first surface 1, and a 1-2 band portion extending from the first connection portion 131a to a portion of the second surface 2, and the second band portion 132b may include a 2-1 band portion extending from the second connection portion 132a to a portion of the first surface 1, and a 2-2 band portion extending from the second connection portion 132a to a portion of the second surface 2.

In the present disclosure, unless specifically contradictory, the description of the band portions 131b and 132b may correspond to the description of each of the first band portion 131a and the second band portion 132a, and furthermore, may correspond to the description of each of the 1-1 band portion, the 1-2 band portion, the 2-1 band portion, and the 2-2 band portion.

The external electrodes 131 and 132 may be formed of any material as long as they have electrical conductivity, such as metal, or the like, and a specific material may be determined in consideration of electrical characteristics, structural stability, or the like, and may further have a multilayer structure.

For example, the external electrodes 131 and 132 may include a first electrode layer disposed on the body 110, and a second electrode layer disposed on the first electrode layer.

Here, it may be preferable that the first and second electrode layers correspond to layers, which are distinguished from each other. However, the present disclosure is not particularly limited, and the first and second electrode layers may be distinguished according to a manufacturing process order, and the first and second electrode layers may be observed as a single layer, without being distinguished from each other.

In the present disclosure, “being distinguished” may mean that two layers are distinguished due to physical, chemical, and/or simple optical characteristics. This is not particularly limited to these factors, as the distinction between the layers may also be based on the presence or absence of an “interface.” An interface may mean a surface where two layers, in contact with each other may be distinguished from each other, and for example, may mean a state in which the two layers may be distinguished by differences in components, such as through EDS analysis using equipment such as a scanning electron microscope (SEM).

The first electrode layer may be formed by transferring a sheet including a conductive metal onto the body 110, or may be formed by applying a conductive paste for an external electrode including a conductive metal to the body 110 and then sintering the same, or may be formed by dipping the body 110 into a conductive paste for an external electrode including a conductive metal, but an embodiment thereof is not particularly limited.

As a more specific example of the first electrode layer, the first electrode layer may be a sintered electrode including a conductive metal and glass.

A material having excellent electrical conductivity may be used as a conductive metal included in the first electrode layer, and for example, may include at least one selected from the group consisting of nickel (Ni), copper (Cu), palladium (Pd), silver (Ag), gold (Au), platinum (Pt), tin (Sn), tungsten (W), titanium (Ti), and alloys thereof, but an embodiment thereof is not particularly limited thereto.

The glass included in the first electrode layer may serve to improve bonding properties with the body 110.

The second electrode layer may play a role in improving mounting characteristics, and may be a plating layer formed on the first electrode layer by plating, but an embodiment thereof is not particularly limited thereto.

The type of the second electrode layer is not particularly limited, and may include, for example, at least one selected from the group consisting of nickel (Ni), tin (Sn), silver (Ag), palladium (Pd), and alloys thereof.

The second electrode layer may be a single layer or may be a plurality of layers.

More specifically, for example, the second electrode layer may include a nickel (Ni) electrode layer or a tin (Sn) electrode layer, and may have a form in which a nickel (Ni) electrode layer and a tin (Sn) electrode layer are sequentially formed on the first electrode layer, or may have a form in which a tin (Sn) electrode layer, a nickel (Ni) electrode layer, and a tin (Sn) electrode layer are sequentially formed. In addition, the second electrode layer may include a plurality of nickel (Ni) electrode layers and/or a plurality of tin (Sn) electrode layers.

A size of the multilayer electronic component 100 is not particularly limited.

However, to achieve both miniaturization and high capacitance, thicknesses of the dielectric layer and internal electrodes should be thinned to increase the number of stacks. Therefore, an effect according to the present disclosure may become more noticeable in a multilayer electronic component 100 having a size of 2012 (length×width: 2.0 mm×1.2 mm, and length and width satisfy an error of within ±10%) or less.

In addition, the multilayer electronic component 100 may have a width greater than a length.

In the present embodiment, the multilayer electronic component 100 may include connection terminals 141 and 142.

The connection terminals 141 and 142 may be disposed to contact a mounting surface of the body 110, for example, band portions 131a and 132b formed on the first surface 1.

More specifically, the connection terminals 141 and 142 may include a first connection terminal 141 disposed to contact the first band portion 131a, and a second connection terminal 142 disposed to contact the second band portion 132a. Here, the first band portion 131a may refer to a 1-1 band portion formed on the first surface 1, and the second band portion 132a may refer to a 2-1 band portion formed on the first surface 1.

The first and second connection terminals 141 and 142 may be connected by being disposed to be in contact with the first and second band portions 131b, and 132b of the first and second external electrodes 131 and 132, respectively.

In addition, the first and second connection terminals 141 and 142 and the first and second external electrodes 131 and 132 may be connected to each other with solder or a conductive paste interposed therebetween, but an embodiment thereof is not particularly limited thereto, and the first and second connection terminals 141 and 142 and the first and second external electrodes 131 and 132 may be connected by being in contact with each other.

The first and second connection terminals 141 and 142 may include a matrix and a metal layer disposed on the matrix.

The matrix of the first and second connection terminals 141 and 142 may include a conductor or an insulator as a main component.

When the matrix of the first and second connection terminals 141 and 142 includes a conductor as a main component, the conductor may include a metal as a main component. The conductor may be any material conducting electricity. For example, the metal may include at least one selected from the group consisting of copper (Cu), aluminum (Al), iron (Fe), and nickel (Ni).

When the matrix of the first and second connection terminals 141 and 142 includes an insulator as a main component, the insulator may include at least one of a PCB including FR4 or F-PCB; and a ceramic including alumina.

The metal layer may play a role in improving bonding strength with the band portions 131a and 132a or improving the electrical conductivity, and may include at least one selected from the group consisting of nickel (Ni), tin (Sn), chromium (Cr), and gold (Au), but an embodiment thereof is not particularly limited thereto.

The metal layer disposed on the insulator may play a role in improving the bonding strength and electrical characteristics with the band portions 131a and 132a, and may include at least one selected from the group consisting of nickel (Ni), tin (Sn), chromium (Cr), and gold (Au), but an embodiment thereof is not particularly limited thereto.

Here, the metal layer may correspond to a plating layer formed by a plating method, and may be disposed in the form of a layer, but an embodiment thereof is not particularly limited thereto.

The first and second connection terminals 141 and 142 may include first and second recess portions 151 and 152, respectively.

The first and second recess portions 151 and 152 may be empty spaces or open space portions, and may serve as solder accommodating portions or solder pockets accommodating solder.

For example, the first and second recess portions 151 and 152 may correspond to at least a portion of a region filled with solder 231 when mounted on a substrate, thereby improving an effect of reducing acoustic noise.

More specifically, the first connection terminal 141 may include a first recess portion 151 in a region recessed toward the fourth surface 4, and the second connection terminal 142 may include a second recess portion 152 in a region recessed toward the third surface 3.

Here, the first and second recess portions 151 and 152 may be provided in adjacent regions, for example, on surfaces or regions, in which the first and second connection terminals 141 and 142 are not adjacent and do not oppose each other, and may be provided on the outside of the first and second connection terminals 141 and 142 in the length direction, and may include a shape recessed in a direction from the outside to the inside thereof.

The first and second recess portions 151 and 152 may play a role in reducing acoustic noise by preventing the solder 231 from being formed on the third and/or fourth surfaces 3 and/or 4 of the capacitor body 110 and reducing a height of the solder, thereby suppressing vibrations of the body 110 from being transmitted to the substrate.

The first and second recess portions 151 and 152 may include curves, and may have a semicircular or a semi-elliptical shape, but the present disclosure is not particularly limited thereto, and may include all recessed shapes such as a square, triangle, or the like.

More specifically, for example, when describing a semicircular or semi-elliptical shape of the first and second recess portions 151 and 152 in more detail with reference to FIG. 3, the first and second connection terminals 141 and 142 may have a shape where the width decreases and then increases again by the first and second recess portions 151 and 152, regions thereof in which the width decreases and then increases again can be referred to as first and second recess portions 151 and 152, respectively. In this case, when maximum lengths of the first and second recess portions 151 and 152 in the length direction are referred to as R1a and R2a, respectively, and ½ of the maximum lengths thereof in the width direction are referred to as R1b and R2b, respectively, when the first and second recess portions 151 and 152 are semicircles, R1a=R1b, R2a=R2b may be satisfied, and when the first and second recess portions are semi-ellipses, R1a≠R1b, R2a≠R2b may be satisfied.

In an embodiment of the present disclosure, a round portion may be provided on at least one corner of the connection terminals 141 and 142.

More specifically, the first connection terminal 141 may include a first inlet portion 151, and may include at least one corner, and the second connection terminal 142 may include a second inlet portion 152, and may include at least one corner.

In this case, a first round portion may be provided on at least one corner of the first connection terminal 141, and a second round portion may be provided on at least one corner of the second connection terminal 142.

Here, a “round portion” may mean that a corner is rounded, or a rounded corner. In addition, the round portion may include a curve, and preferably, it can correspond to a region formed by a curve.

By forming a round portion on at least one corner of the connection terminals 141 and 142, the force applied to the multilayer electronic component 100 when mounted on a substrate 210 using solder 231 may be dispersed, thereby improving mountability.

In this case, it may be preferable that a first round portion is provided at a corner of the first connection terminal 141, which is not adjacent to the second connection terminal 142, and a second round portion is provided at a corner of the second connection terminal 142, which is not adjacent to the first connection terminal 141.

In addition, it may be preferable that the first round portion is provided at the outermost corner in the width direction of the first connection terminal 141, and the second round portion is provided at the outermost corner in the width direction of the second connection terminal 142.

In addition, it may be preferable that the first round portion is provided at a corner, which is adjacent to the third surface 3, among the corners of the first connection terminal 141, and the second round portion is provided at a corner, which is adjacent to the fourth surface 4, among the corners of the second connection terminal 142.

In addition, it may be preferable that the first round portion is provided at least two corners opposing each other in the width direction among the corners of the first connection terminal 141, and the second round portion is provided at least two corners opposing each other in the width direction among the corners of the second connection terminal 142.

By forming a round portion at the corner of the connection terminals 141 and 142 described above, the force applied to the multilayer electronic component 100 when mounted on a substrate 210 using solder 231 may be further dispersed to further improve mountability.

In this case, it may be preferable that radii of the round portion is 30 μm or more and 196 μm or less.

By satisfying the radii of the first and second round portions to be 30 μm or more and 196 μm or less, the mountability may be improved.

When the radii of the first and second round portions is less than 30 μm or more than 196 μm, there is a risk that the mountability may be reduced and mounting defects may occur.

A method for measuring the radius of the round portion is not particularly limited, but the method may be measured in the following manners. Referring to FIG. 3, when describing a first round portion in more detail, a first round portion among a plurality of corners of the first connection terminal 141 may be provided at the outermost corner, which is not adjacent to the second connection terminal 142 but opposes each other based on the width direction. In other words, the first round portion may be provided at an upper left corner and a lower left corner of the first connection terminal 141, respectively. In this case, a radius R of the first round portion provided at the upper left corner of the first connection terminal 141 may be obtained from an imaginary circle having a center of Rc, which is a portion of the circle, with a P1 point, which begins to deviate from an EL1 and a P2 point, which begins to deviate from an EL2, based on the extension line EL1 of a surface thereof formed in the length direction (X-direction) and the extension line EL2 of the surface formed in the width direction (Y-direction). The first round portion provided at the upper left corner of the first connection terminal 141 has been described as an example, but it will be obvious to a person skilled in the art that the radius of the round portion may be obtained in the same manner for the first round portion provided at the lower left corner of the first connection terminal 141 and the second round portions provided at the upper right corner and lower right corner of the second connection terminal 142.

A ratio of an average thickness “Tcr” of recess portions 151′ and 152′ to an average thickness “Tct” of connection terminals 141′ and 142′ may be 50% or more and 100% or less.

That is, a ratio of the average thickness of the first recess portion 151′ to the average thickness of the first connection terminal 141′ may be 50% or more and 100% or less, and a ratio of the average thickness of the second recess portion 152′ to the average thickness of the second connection terminal 142′ may be 50% or more and 100% or less.

By satisfying the ratio of the average thickness “Tcr” of the recess portions 151′ and 152′ to the average thickness “Tct” of the connection terminals 141′ and 142′ to be 50% or more and 100% or less, solder may be sufficiently accommodated, and thus an effect of reducing acoustic noise may be further improved.

In this case, when the ratio of the average thickness “Tcr” of the recess portions 151 and 152 to the average thickness “Tct” of the connection terminals 141′ and 142′ is 50% or more and less than 100%, the recess portions 151′ and 152′ may be provided on the outside thereof in the thickness direction from the first surface 1. In other words, the recess portions 151′ and 152′ may be provided below the connection terminals 141′ and 142′ in the thickness direction, which is a region close to the mounting surface.

When the ratio of the average thickness “Tcr” of the recess portions 151′ and 152′ to the average thickness “Tct” of the connection terminals 141′ and 142′ is 50% or more and less than 100%, the recess portions 151′ and 152′ may be provided on the outside thereof in the thickness direction from the first surface 1, so that a space for accommodating solder may be more easily secured.

Meanwhile, the fact that the ratio of the average thickness “Tcr” of the recess portions 151 and 152 to the average thickness “Tct” of the connection terminals 141 and 142 is 100% may mean that the recess portions 151 and 152 penetrates a portion of the connection terminals 141 and 142 in the thickness direction.

### Mounting Substrate of Multilayer Electronic Component

A mounting substrate 1000 of a multilayer electronic component according to another embodiment of the present disclosure may include a substrate 210; first and second electrode pads 221 and 222 disposed on the substrate 210; and the multilayer electronic component 100 described above, wherein the first and second connection terminals 141 and 142 may be mounted on the substrate 210 to be bonded to the first and second electrode pads 221 and 222, respectively, and solder 231 may be disposed on at least a portion of the first and second recess portions 151 and 152.

In the present embodiment, the description of the multilayer electronic component 100 overlapping the description of the multilayer electronic component 100 described above, so the description thereof will be omitted.

The multilayer electronic component 100 may be connected to the first and second electrode pads 221 and 222 by solder 231 disposed on lower surfaces of the first and second connection terminals 141 and 142, and since the solder 231 does not increase to of the third and/or fourth surfaces 3 and/or 4 of the body in the length direction, acoustic noise or vibrations generated in the multilayer electronic component 100 and transmitted to the substrate 210 may be reduced.

The mounting substrate 1000 of the multilayer electronic component of the present embodiment has no restrictions on a mounting direction, and for example, in both cases in which the internal electrodes 121 and 122 stacked on the body 110 are stacked horizontally or vertically with respect to a mounting surface, the acoustic noise improvement effect and the mountability improvement effect can be secured.

Hereinafter, the present disclosure will be described in more detail through Test Examples, but this is only to help a specific understanding of the disclosure, and the scope of the present disclosure is not limited by the Test Examples.

### Test Example

Table 1 below illustrates the results of the mountability evaluation for Test Examples 1 to 6.

Test Example 1 corresponds to a chip including a body including a dielectric layer and an internal electrode, an external electrode disposed on the body, and a connection terminal disposed on a lower surface of the external electrode. In this case, the connection terminal had a recess portion formed and a round portion formed at the corner as shown in FIG. 3, and a radius thereof was manufactured to be 15 μm.

Test Example 2 was manufactured in the same manner as Test Example 1, except that the radius was 93 μm.

Test Example 3 was manufactured in the same manner as Test Example 1, except that the radius was 121 μm.

Test Example 4 was manufactured in the same manner as Test Example 1, except that the radius was 121 μm.

Test Example 5 was manufactured in the same manner as Test Example 1, except that the radius was 196 μm.

Test Example 6 was manufactured in the same manner as Test Example 1, except that the radius was 250 μm.

For the mountability evaluation, after a reflow process was performed, after 2,000 chips were mounted on a substrate by applying solder for each test example, how far each chip is from a center point in a length direction (x direction) and a width direction (y direction) was measured using Automated Optical Inspection (AOI), and chips that are more than 150 μm away from the center point in at least one of the length direction and width direction were evaluated as defective, and a defect rate was described in Table 1

TABLE 1

| | Radius (μm) | | Mounting defect rate (%) |
|---|---|---|---|
| Test Example 1 | 15 | μm | 0.4% |
| Test Example 2 | 30 | μm | 0% |
| Test Example 3 | 93 | μm | 0% |
| Test Example 4 | 121 | μm | 0% |
| Test Example 5 | 196 | μm | 0% |
| Test Example 6 | 250 | μm | 0.1% |

Test Example 1, in which the radius of the round portion was 15 μm, was evaluated to have a defect rate of 0.4%. Test Examples 2 to 5, in which the radii of the round portions were 30 μm, 93 μm, 121 μm, and 196 μm, respectively, were evaluated to have a defect rate of 0%. Test Example 6, in which the radius of the round portion was 250 μm, was evaluated to have a defect rate of 0.1%.

Therefrom, it can be confirmed that when a round portion having a radius of 30 μm or more and 196 μm or less is formed at the corner of the connection terminal, the mounting performance is improved when mounting to a substrate using solder.

As set forth above, as one of the many effects of the present disclosure, acoustic noise of a multilayer electronic component may be improved.

As one of the many effects of the present disclosure, mountability of a multilayer electronic component may be improved.

However, various advantages and effects of the present disclosure are not limited to the above-described contents, and can be more easily understood in a process of explaining specific embodiments of the present disclosure.

Although the embodiments of the present disclosure have been described in detail above, the present disclosure is not limited by the above-described embodiments and the attached drawings, but is intended to be limited by the appended claims. Accordingly, various forms of substitution, modification, and change may be made by those skilled in the art within the scope that does not depart from the technical idea of the present disclosure described in the claims, and this will also fall within the scope of the present disclosure.

In addition, the expression ‘an embodiment’ used in this specification does not mean the same embodiment, and may be provided to emphasize and describe different unique characteristics. However, an embodiment presented above may not be excluded from being implemented in combination with features of another embodiment. For example, although the description in a specific embodiment is not described in another example, it can be understood as an explanation related to another example, unless otherwise described or contradicted by the other embodiment.

The terms used in this disclosure are used only to illustrate various examples and are not intended to limit the present inventive concept. Singular expressions include plural expressions unless the context clearly dictates otherwise.

While example embodiments have been illustrated and described above, it will be apparent to those skilled in the art that modifications and variations could be made without departing from the scope of the present disclosure as defined by the appended claims.

What is claimed is:

1. A multilayer electronic component, comprising:
a body including a dielectric layer and an internal electrode alternately disposed with the dielectric layer interposed therebetween in a thickness direction, the body including first and second surfaces opposing each other in the thickness direction, third and fourth surfaces connected to the first and second surfaces and opposing each other in a length direction, and fifth and sixth surfaces connected to the first to fourth surfaces and opposing each other in a width direction;
a first external electrode including a first connection portion disposed on the third surface, and a first band portion disposed to extend from the first connection portion to a portion of the first and second surfaces;
a second external electrode including a second connection portion disposed on the fourth surface, and a second band portion disposed to extend from the second connection portion to a portion of the first and second surfaces;
a first connection terminal disposed to contact the first band portion, and including a first recess portion in a region recessed toward the fourth surface; and
a second connection terminal disposed to contact the second band portion, and including a second recess portion in a region recessed toward the third surface,
wherein a first round portion is provided on at least one corner of the first connection terminal, and a second round portion is provided on at least one corner of the second connection terminal, and
radii of the first and second round portions are 30 μm or more and 196 μm or less.

2. The multilayer electronic component of claim 1, wherein the first round portion is provided at a corner of the first connection terminal, adjacent to the second connection terminal, and
the second round portion is provided at a corner of the second connection terminal, adjacent to the first connection terminal.

3. The multilayer electronic component of claim 1, wherein the first round portion is provided at an outermost corner in the width direction among the corners of the first connection terminal, and
the second round portion is provided at an outermost corner in the width direction among the corners of the second connection terminal.

4. The multilayer electronic component of claim 1, wherein the first round portion is provided at a corner of the first connection terminal, adjacent to the first recess portion, and
the second round portion is provided at a corner of the second connection terminal, adjacent to the second recess portion.

5. The multilayer electronic component of claim 1, wherein the first and second recess portions include a semicircular or semi-elliptical shape.

6. The multilayer electronic component of claim 1, wherein a ratio of an average thickness of the first recess portion to an average thickness of the first connection terminal is 50% or more and 100% or less, and
a ratio of an average thickness of the second recess portion to an average thickness of the second connection terminal is 50% or more and 100% or less.

7. The multilayer electronic component of claim 6, wherein
the first and second recess portions are provided on an outside of the first and second connection terminals in the thickness direction from the first surface, respectively.

8. The multilayer electronic component of claim 1, wherein the first and second connection terminals include a matrix and a metal layer disposed on the matrix, and
a main component of the matrix comprises at least one of a conductor or an insulator.

9. The multilayer electronic component of claim 8, wherein the conductor comprises a metal as a main component, and
the metal comprises at least one selected from the group consisting of copper (Cu), aluminum (Al), iron (Fe), and nickel (Ni).

10. The multilayer electronic component of claim 8, wherein the insulator comprises at least one of a PCB including FR4 or F-PCB, and a ceramic including alumina.

11. The multilayer electronic component of claim 8, wherein the metal layer comprises at least one selected from the group consisting of nickel (Ni), tin (Sn), chromium (Cr), and gold (Au).

12. A mounting substrate of a multilayer electronic component, comprising:
a substrate;
first and second electrode pads disposed on the substrate; and
the multilayer electronic component of claim 1,
wherein the first and second connection terminals are mounted on the substrate to be bonded to the first and second electrode pads, respectively, and
solder is disposed on at least a portion of the first and second recess portions.
